(19) United States
(12) Patent Application Publication
(10) Pub. No.: US 2025/0081718 A1
(43) Pub. Date: Mar. 6, 2025

(54) LIGHT EMITTING DEVICE AND DISPLAY PANEL

(71) Applicant: BOE TECHNOLOGY GROUP CO., LTD., Beijing (CN)

(72) Inventors: Xiaobo DU, Beijing (CN); Yansong LI, Beijing (CN); Erli LI, Beijing (CN); Shu JING, Beijing (CN); Yonghong CHEN, Beijing (CN); Mingli LIU, Beijing (CN)

(21) Appl. No.: 18/282,849

(22) PCT Filed: Jan. 16, 2023
(86) PCT No.: PCT/CN2023/072404

§ 371 Date: Sep. 19, 2023

(51) Int. Cl. H10K 50/12; H10K 50/15; H10K 50/16; H10K 50/17; H10K 101/00; H10K 101/10; H10K 101/25; H10K 102/00

(52) U.S. Cl. CPC H10K 50/12; H10K 50/15; H10K 50/16; H10K 50/171; H10K 2101/10; H10K 2101/25; H10K 2101/27; H10K 2101/90; H10K 2102/351

(57) ABSTRACT

The present disclosure provides a light emitting device and a display panel, which belong to the field of display technology. The light emitting device includes a first electrode, a second electrode, and at least one light emitting unit between the first electrode and the second electrode; the at least one light emitting unit each at least includes a light emitting layer; the light emitting layer includes a host material, a phosphorescent guest material and a fluorescent guest material which are doped together; a lowest triplet energy level of at least one material in the host material is greater than a lowest triplet energy level of the phosphorescent guest material.

### TECHNICAL FIELD

The present disclosure relates to the field of display technology, and in particular to a light emitting device and a display panel.

### BACKGROUND

An organic light emitting diode (OLED) generally emits light in a phosphorescence manner or a fluorescence manner, and a main difference therebetween is that guest materials used in a light emitting layer in the phosphorescence manner and in the fluorescence manner are different, namely, a phosphorescence material and a fluorescence material, respectively. Triplet excitons and singlet excitons in the phosphorescence material may return to the ground level and emit light by radiation, so that the internal quantum efficiency (IQE) may theoretically reach 100%. The intersystem transition between the triplet state and the singlet state in the fluorescence material is forbidden, so that the triplet excitons cannot return to the ground level to emit light, and only the singlet excitons may be used to emit light, and thus internal quantum efficiency IQE may only reach 25% theoretically, and therefore, the IQE of the light emitting device using the fluorescence material is often low.

### SUMMARY

The present disclosure is directed to solving at least one of the technical problems in the related art, and provides a light emitting device and a display panel.

In a first aspect, the technical solution of the present disclosure adopted to solve the technical problem is a light emitting device, including a first electrode, a second electrode, and at least one light emitting unit between the first electrode and the second electrode; wherein the at least one light emitting unit includes at least a light emitting layer; wherein the light emitting layer includes a host material, a phosphorescent guest material and a fluorescent guest material which are doped together; and a lowest triplet energy level of at least one material in the host material is greater than a lowest triplet energy level of the phosphorescent guest material.

In some embodiments, the light emitting layer of the at least one light emitting unit emits light with a wavelength between 440 nm and 480 nm.

In some embodiments, a peak of a photoluminescence spectrum of the phosphorescent guest material is between 440 nm and 520 nm.

In some embodiments, a peak width at half height of the photoluminescence spectrum of the phosphorescent guest material is less than 160 nm.

In some embodiments, a peak of an absorption spectrum of the fluorescent guest material is between 420 nm and 480 nm.

In some embodiments, a peak of a photoluminescence spectrum of the fluorescent guest material is between 440 nm and 520 nm.

In some embodiments, the lowest triplet energy level of the phosphorescent guest material is between 2.6 ev and 3.2 ev.

In some embodiments, a peak of a photoluminescence spectrum of the at least one material in the host material is between 360 nm and 500 nm.

In some embodiments, a peak width at half height of an electroluminescence spectrum of the light emitting device is less than 80 nm.

In some embodiments, the host material is a mixture of at least two materials.

In some embodiments, the host material is a mixture of at least two materials; and excitons in the light emitting layer are recombined to form exciplexes in operation.

In some embodiments, a peak of a photoluminescence spectrum of the host material is between 360 nm and 520 nm.

In some embodiments, the host material is a mixture of at least two materials; and the minimum mixing proportion of any one of the at least two materials is greater than 5%.

In some embodiments, a doping concentration of the phosphorescent guest material is between 1% and 30%.

In some embodiments, a doping concentration of the fluorescent guest material is between 0.1% and 5%.

In some embodiments, the at least one light emitting unit further includes functional sub-layers; and the functional sub-layers include at least one of a P-type doped hole transport layer, a hole transport layer, a light emitting prime layer, a hole blocking layer, an electron transport layer and an electron injection layer.

In some embodiments, the functional sub-layers include the light emitting prime layer, and a lowest triplet energy level of a material of the light emitting prime layer is greater than 2.7 ev; and the functional sub-layers include the hole blocking layer, and a lowest triplet energy level of a material of the hole transport layer is greater than 2.7 ev.

In some embodiments, the at least one light emitting unit includes one light emitting unit; the functional sub-layers include the P-type doped hole transport layer, and a thickness of the P-type doped hole transport layer is between 2 nm and 50 nm; the functional sub-layers include the hole transport layer, and a thickness of the hole transport layer is between 5 nm and 200 nm; the functional sub-layers include the light emitting prime layer, and a thickness of the light emitting prime layer is between 3 nm and 30 nm; a thickness of the light emitting layer is between 5 nm and 50 nm; the functional sub-layers include the hole blocking layer, and a thickness of the hole blocking layer is between 3 nm and 30 nm; the functional sub-layers include the electron transport layer, and a thickness of the electron transport layer is between 10 nm and 40 nm; and the functional sub-layers include the electron injection layer, and a thickness of the electron injection layer is between 0.5 nm and 5 nm.

In some embodiments, the at least one light emitting unit includes a plurality of light emitting units; and the light emitting device further includes a charge separation generation unit between every two adjacent light emitting units.

In some embodiments, the functional sub-layers include the hole transport layer, and a thickness of the hole transport layer is between 10 nm and 300 nm; the functional sub-layers include the light emitting prime layer, a thickness of the light emitting prime layer is between 3 nm and 80 nm; a thickness of the light emitting layer is between 10 nm and 40 nm; the functional sub-layers include the hole blocking layer, a thickness of the hole blocking layer is between 5 nm and 20 nm; the functional sub-layers include the electron transport layer, a thickness of the electron transport layer is between 10 nm and 30 nm; and the charge separation generation unit includes an N-type doped charge generation layer and a P-type doped charge generation layer; and a thickness of the N-type doped charge generation layer and a thickness of the P-type doped charge generation layer are both between 5 nm and 30 nm.

In some embodiments, the host material includes a P-type material; the P-type material includes a material containing one of the molecular structures of CBP, MCBP, carbazole, triphenylamine; or the P-type material includes a material containing one of the molecular structures of a CBP derivative, a carbazole derivative, and a triphenylamine derivative.

In some embodiments, the host material includes an N-type material; the N-type material includes a material containing one of the molecular structures of pyridine, triazine, phenylimidazole; or the N-type material includes a material containing one of the molecular structures of a pyridine derivative, a triazine derivative, and a phenylimidazole derivative.

In some embodiments, the host material includes a bipolar material, and a ratio of a first mobility of the bipolar material for transporting electrons to a second mobility of the bipolar material for transporting holes is between 1 and 10.

In some embodiments, the host material includes a first host material and a second host material, the first host material is a P-type material and the second host material is an N-type material.

In some embodiments, the highest occupied molecular orbital (HOMO) energy level of the host material is between −5.2 eV and −6.0 eV; and the lowest unoccupied molecular orbital (LUMO) energy level of the host material is between −2.1 eV and −2.8 eV.

In some embodiments, a bandgap of the host material is less than 3.7 ev; and the bandgap of the host material is an absolute value of a difference between the HOMO energy level and the LUMO energy level of the host material.

In some embodiments, the host material includes a first host material, a second host material and a third host material, wherein the first host material is a P-type material, the second host material is an N-type material, and the third host material is a bipolar material.

In some embodiments, the phosphorescent guest material includes a coordination compound of platinum or a coordination compound of iridium.

In some embodiments, the fluorescent guest material includes a material containing one of the molecular structures of indolocarbazole, pyrene; or the fluorescent guest material includes a material containing one of molecular structures of an indolocarbazole derivative and a pyrene derivative.

In a second aspect, an embodiment of the present disclosure further provides a display panel, including the light emitting device in any one of the above embodiments.

### BRIEF DESCRIPTION OF DRAWINGS

FIG. 1 is a schematic diagram of a structure of a light emitting device according to an embodiment of the present disclosure;

FIG. 2 is a schematic diagram illustrating energy transfer within a light emitting layer according to an embodiment of the present disclosure;

FIG. 3 is a schematic diagram of a specific structure of a light emitting unit according to an embodiment of the present disclosure;

FIG. 4 is a schematic diagram of a specific structure of another light emitting device according to an embodiment of the present disclosure;

FIG. 5 is a schematic diagram of a specific structure of a tandem light emitting device according to an embodiment of the present disclosure; and

FIG. 6 is a schematic diagram of a specific structure of another tandem light emitting device according to an embodiment of the present disclosure.

Reference numbers are: 1. a first electrode; 2. a second electrode; 3. a light emitting unit; B-EML, a blue light emitting layer; G-EML, a green light emitting layer; R-EML, a red light emitting layer; T1, a lowest triplet energy level; P-DOPANT, a P-type doped hole transport layer; HTL, a hole transport layer; B Prime, a light emitting prime layer; HBL, a hole blocking layer; ETL, an electron transport layer; EIL, an electron injection layer; CPL, a light extraction layer; 4. a charge separation generation unit; N-CGL, an N-type doped charge generation layer; P-CGL, a P-type doped charge generation layer; 31. a first light emitting unit; 32. a second light emitting unit.

### DETAIL DESCRIPTION OF EMBODIMENTS

To make an object, a technical solution and an advantage of the embodiments of the present disclosure more apparent, the technical solution in the embodiment of the present disclosure will be described clearly and completely with reference to the drawings in the embodiment of the present disclosure. Obviously, the described embodiments are only a part, not all, of the embodiments of the present disclosure. Components of the embodiments of the present disclosure, as generally described and illustrated in the drawings herein, could be arranged and designed in a wide variety of different configurations. Thus, the following detailed description of the embodiments of the present disclosure provided in the drawings is not intended to limit the claimed scope of the present disclosure, but is merely representative of selected embodiments of the present disclosure. All other embodiments, which can be derived by a person skilled in the art from the embodiments of the present disclosure without any creative effort, shall fall within the protection scope of the present disclosure.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term of “comprising”, “including”, or the like, means that the element or item preceding the term contains the element or item listed after the term and its equivalent, but does not exclude other elements or items. The term “connected”, “coupled”, or the like is not limited to physical or mechanical connections, but may include electrical connections, whether direct or indirect connections. The terms “upper”, “lower”, “left”, “right”, and the like are used only for indicating relative positional relationships, and when the absolute position of an object being described is changed, the relative positional relationships may also be changed accordingly.

Reference to “a plurality or a number” in this disclosure means two or more. “And/or” describes the association between the associated objects, indicating that there may be three relationships, for example, A and/or B, which may indicate: A exists alone, A and B exist simultaneously, and B exists alone. The character “/” generally indicates that the associated objects are in an “or” relationship therebetween.

In the related art, a blue fluorescent device utilizes the triplet-triplet annihilation (TTA) effect, so that the triplet excitons are quenched to generate the singlet excitons, thereby further increasing the number of available excitons. However, a great part of the triplet excitons are quenched through the TTA effect, so that the maximum IQE of the blue fluorescent device theoretically can only reach 40% even if the TTA effect is utilized, which is much lower than that of a phosphorescent device. Therefore, the phosphorescent device has a great advantage in efficiency. Currently, a phosphorescent OLED device is mainly used in mass-produced red and green devices. A blue phosphorescent device has a great advantage in efficiency, but lowest triplet (T1) energy levels of a blue phosphorescent guest and a host material each are higher than T1 energy levels of each of red and green phosphorescence materials, so that the triplet excitons collide and recombine in the triplet-triplet annihilation (TTA) process and the triplet-polaron annihilation (TPA) process due to the higher energy, and excitons and polarons with higher energy are generated. The excitons with higher energy can damage chemical bonds of organic materials, so that the materials are degraded, and the service life of the device is greatly reduced. Therefore, the service life of the blue phosphorescent device is often shorter, and the requirement of mass production products cannot be met.

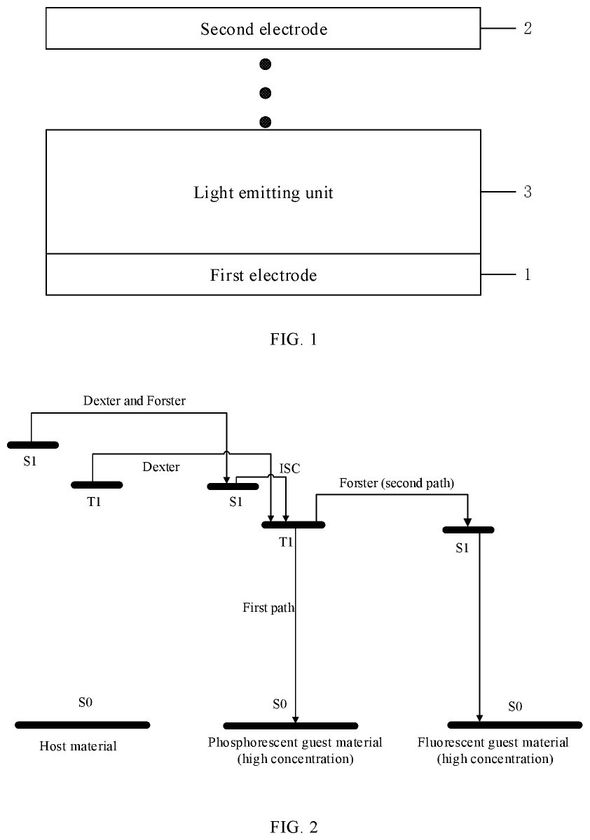

Based on this, the embodiment of the present disclosure provides a light emitting device, which may be a red light emitting device, a green light emitting device, or a blue light emitting device. FIG. 1 is a schematic diagram of a structure of a light emitting device according to an embodiment of the present disclosure. As shown in FIG. 1, the light emitting device includes a first electrode 1, a second electrode 2, and at least one light emitting unit 3 disposed between the first electrode 1 and the second electrode 2; the at least one light emitting unit 3 includes at least a light emitting layer. One of the first electrode 1 and the second electrode 2 is an anode, and the other is a cathode. For convenience of understanding, as an example, the first electrode 1 is used as an anode and the second electrode 2 is used as a cathode in the following embodiments of the present disclosure.

The light emitting layer includes a host material, a phosphorescent guest material and a fluorescent guest material which are doped together; a lowest triplet energy level T1 of at least one material in the host material is greater than a lowest triplet energy level T1 of the phosphorescent guest material.

FIG. 2 is a schematic diagram of energy transfer within a light emitting layer according to an embodiment of the present disclosure. As shown in FIG. 2, the singlet excitons in the host material undergo the Dexter energy transfer and the Forster energy transfer, i.e., the singlet excitons are transferred from a first singlet S1 energy level of the host material to an S1 energy level of the phosphorescent guest material. The triplet excitons in the host material undergo the Dexter energy transfer and are transferred from the T1 energy level of the host material to the T1 energy level of the phosphorescent guest material. The singlet excitons of the phosphorescent guest material undergo intersystem crossing (ISC) and transition from the S1 energy level to the T1 energy level. The triplet excitons of the phosphorescent guest material may return to an ground state S0 energy level through two different paths, namely a first path and a second path.

In the embodiment of the present disclosure, the phosphorescent guest material is doped in the host material. The phosphorescent guest material may simultaneously include the singlet excitons and the triplet excitons, the theoretical IQE can reach 100%. Meanwhile, the fluorescent guest material is doped in the host material, and the phosphorescent guest material and the fluorescent guest material cooperate with each other. Specifically, the triplet excitons in the phosphorescent guest material may return to the ground state S0 energy level through two different paths to emit light, wherein the triplet excitons in the phosphorescent guest material may return to the ground state S0 energy level through the first path to emit light, and may be transferred to a first singlet S1 energy level of the fluorescent guest material through the second path and then return to the ground state S0 energy level through the S1 energy level of the fluorescent guest material to emit light. The energy transfer process disperses the triplet excitons gathered in the phosphorescent guest material to a certain extent, reduces a concentration of the excitons on the T1 energy level of the phosphorescent guest material, greatly reduces the possibility of the TTA and TPA processes, avoids the damage of the excitons in a high energy level on chemical bonds of the organic material, and thus can greatly prolong the service life of the light emitting device. Therefore, in the embodiment of the present disclosure, the phosphorescent guest material and the fluorescent guest material are doped in the host material, so that the efficiency of the light emitting device can be improved, and the service life of the light emitting device can be greatly prolonged.

In some embodiments, the light emitting layer in the at least one light emitting unit emits light with a wavelength between 440 nm to 480 nm. That is, the light emitting layer is a blue light emitting layer B-EML. The blue light emitting layer B-EML includes a blue host material, a blue phosphorescent guest material, and a blue fluorescent guest material doped together. If the light emitting device in the present disclosure is a blue light emitting device, the efficiency of the blue light emitting device is much higher than that of a blue fluorescent device under a same condition.

Illustratively, in the case where the light emitting device includes only one light emitting unit 3, the light emitting layer is the blue light emitting layer B-EML, and the light emitting device is the blue light emitting device including the blue host material, the blue phosphorescent guest material, and the blue fluorescent guest material doped together, so that the efficiency of the light emitting device is improved, and the service life of the light emitting device is greatly prolonged. Meanwhile, the efficiency of the blue light emitting device of the embodiment of the present disclosure is much higher than that of the blue fluorescent device under a same condition.

Further illustratively, in the case where the light emitting device includes a plurality of light emitting units 3, that is, a tandem light emitting device, the light emitting device may be the blue light emitting device, or may be a light emitting device that emits light of a color other than the blue light. Here, as an example, the light emitting device is the blue light emitting device, and the blue light emitting device includes two light emitting units 3, where the light emitting layer of one light emitting unit 3 includes the blue host material, the blue phosphorescent guest material, and the blue fluorescent guest material doped together; the light emitting layer of the other light emitting unit 3 is a pure blue phosphorescence material. Here, the efficiency of the blue light emitting device can be further improved by providing the light emitting layer of the pure blue phosphorescence material on the basis of satisfying the service life of the light emitting device.

Further illustratively, in the case where the light emitting device includes a plurality of light emitting units 3, that is, the tandem light emitting device, the light emitting device may be the blue light emitting device, or may be a light emitting device that emits light of a color other than the blue light. Here, as an example, the light emitting device is the blue light emitting device, and the blue light emitting device includes two light emitting units 3, where the light emitting layer of one light emitting unit 3 includes the blue host material, the blue phosphorescent guest material, and the blue fluorescent guest material doped together; the light emitting layer of the other light emitting unit 3 is a pure blue fluorescence material. Here, the service life of the light emitting device can be further improved by providing the light emitting layer of the pure blue fluorescence material on the basis of satisfying the efficiency of the light emitting device.

The present disclosure will be specifically described below by taking an example in which the light emitting device is the blue light emitting device.

In some embodiments, a peak of the photoluminescence spectrum of the phosphorescent guest material is between 440 nm and 520 nm. Here, the photoluminescence spectrum of the phosphorescent guest material specifically refers to a photoluminescence spectrum of an organic film doped with the phosphorescent guest material. Illustratively, a doping concentration of the phosphorescent guest material is 5%. The organic film may be a polymethyl methacrylate PMMA film. Specifically, the phosphorescent guest material is doped into the organic polymer PMMA to form the PMMA film with the doping concentration of 5%, and a peak of the photoluminescence spectrum of the PMMA film is between 440 nm and 520 nm. It should be noted that the doping concentration is understood as a mass ratio of the phosphorescent guest material to the polymethyl methacrylate PMMA.

In some embodiments, a peak width at half height of the photoluminescence spectrum of the phosphorescent guest material is less than 160 nm, so that a higher color purity can be obtained. Preferably, the peak width at half height of the photoluminescence spectrum of the phosphorescent guest material is 100 nm, so that a higher color purity can be further obtained.

In some embodiments, a peak of an absorption spectrum of the fluorescent guest material is between 420 nm and 480 nm. Here, the absorption spectrum of the fluorescent guest material specifically means an absorption spectrum of an organic film doped with the fluorescent guest material. Illustratively, a doping concentration of the fluorescent guest material is 5%. The organic film may be a PMMA film. Specifically, the fluorescent guest material is doped into the organic polymer PMMA to form the PMMA film with the doping concentration of 5%, and the peak of the absorption spectrum of the PMMA film is between 420 nm and 480 nm. It should be noted that the doping concentration is understood as a mass ratio of the fluorescent guest material to the PMMA.

The peak of the absorption spectrum of the fluorescent guest material is close to a range of the peak of the photoluminescence spectrum of the phosphorescent guest material as much as possible. That is, the higher overlapping area between the photoluminescence spectrum of the phosphorescent guest material and the absorption spectrum of the fluorescent guest material is obtained, so that the energy transfer efficiency is improved, more excitons are transferred from the phosphorescent guest material to the fluorescent guest material, the quenching of the excitons is effectively prevented, the damage of the excitons in a high energy level on chemical bonds of the organic material is avoided, and the service life of the light emitting device can be greatly prolonged.

In some embodiments, the peak of the photoluminescence spectrum of the fluorescent guest material is between 440 nm and 520 nm. Here, the photoluminescence spectrum of the fluorescent guest material specifically refers to a photoluminescence spectrum of an organic film doped with the fluorescent guest material. Illustratively, the doping concentration of the fluorescent guest material is 5%. The organic film may be the PMMA film. Specifically, the fluorescent guest material is doped into the organic polymer PMMA to form the PMMA film with the doping concentration of 5%.

In some embodiments, the lowest triplet energy level T1 of the phosphorescent guest material is between 2.6 ev and 3.2 ev.

In some embodiments, the peak of the photoluminescence spectrum of the at least one material in the host material is between 360 nm and 500 nm. The photoluminescence spectrum here specifically refers to a photoluminescence spectrum of a solid pure film of the at least one material in the host material.

The host material may be a single material or a mixture of two or more materials. If the host material is a single material, a peak of the photoluminescence spectrum of the single material is between 360 nm and 500 nm. If the host material is a mixture of two or more materials, a peak of the photoluminescence spectrum of at least one material in the mixture is between 360 nm and 500 nm.

In some embodiments, a peak width at half height of the electroluminescence spectrum of the light emitting device is less than 80 nm, so that a higher color purity can be further obtained. Preferably, the peak width at half height of the electroluminescence spectrum of the light emitting device is between 10 nm and 40 nm, so that a higher color purity can be further obtained.

In some embodiments, the host material is formed by mixing at least two materials. It should be noted that a light emitting mechanism of the light emitting device OLED is: when a voltage is applied between an anode and a cathode, holes injected from the anode enter the light emitting layer EML and electrons injected from the cathode enter the light emitting layer EML under the driving of the external voltage, and the holes and the electrons entering the light emitting layer EML are recombined in a recombination region to form excitons, thereby emitting light by radiative transition of the excitons, that is, achieving the electroluminescence. In the embodiment, on the premise that the host material of the light emitting layer EML is formed by mixing at least two materials, the excitons are generated in the light emitting layer EML in the operating process of the light emitting device, which includes two cases, that is, the excitons are not recombined; and the excitons are recombined to form exciplexes.

In some embodiments, a peak of a photoluminescence spectrum of the host material is between 360 nm and 520 nm. Here, the photoluminescence spectrum of the host material specifically refers to a photoluminescence spectrum of a solid pure film obtained by mixing at least two materials in a certain ratio (for example, mixing the materials in an equal ratio).

In some embodiments, the host material is formed by mixing at least two materials, and the minimum mixing proportion of any one of the at least two materials is greater than 5%. Illustratively, the host material is formed by mixing two materials, a mixing proportion of a material A is 50%, and a mixing proportion of a material B is 50%. Alternatively, the host material is formed by mixing three materials, wherein a mixing proportion of the material A is 40%, a mixing proportion of a material B is 30%, and a mixing proportion of a material C is 30%.

In some embodiments, the doping concentration of the phosphorescent guest material is between 1% and 30%. It should be noted that the doping concentration here is understood to be a mass ratio of the phosphorescent guest material to the host material (or the host material+the fluorescent guest material).

In some embodiments, the doping concentration of the fluorescent guest material is between 0.1% and 5%. It should be noted that the doping concentration here is understood to be a mass ratio of the fluorescent guest material to the host material (or the host material+the phosphorescent guest material).

It is described in the related art that the T1 energy level of each of the blue phosphorescent guest material and the host material is higher than the T1 energy level of each of the red and green phosphorescence materials, so that the triplet excitons collide and recombine in the TTA process and the TPA process due to the higher energy, and excitons and polarons with higher energy are generated. The excitons with higher energy can damage chemical bonds of organic materials, so that the materials are degraded, and the service life of the device is greatly reduced. In the above embodiments of the present disclosure, specifically, the following items satisfy the above conditions: the T1 energy level, the peak and the peak width at half height of the photoluminescence spectrum of the phosphorescent guest material, the peak of the absorption spectrum and the peak of the photoluminescence spectrum of the fluorescent guest material, the peak of the photoluminescence spectrum of the blue host material, and the relationship between the T1 energy level of the blue host material and the T1 energy level of the phosphorescent guest material, and the like in the blue light emitting layer EML in the blue light emitting device, so that the energy transfer between the phosphorescent guest material and the fluorescent guest material has a higher conversion rate, and the color purity of the blue light emitting device is improved, and finally, the blue phosphorescent device with better performance is obtained.

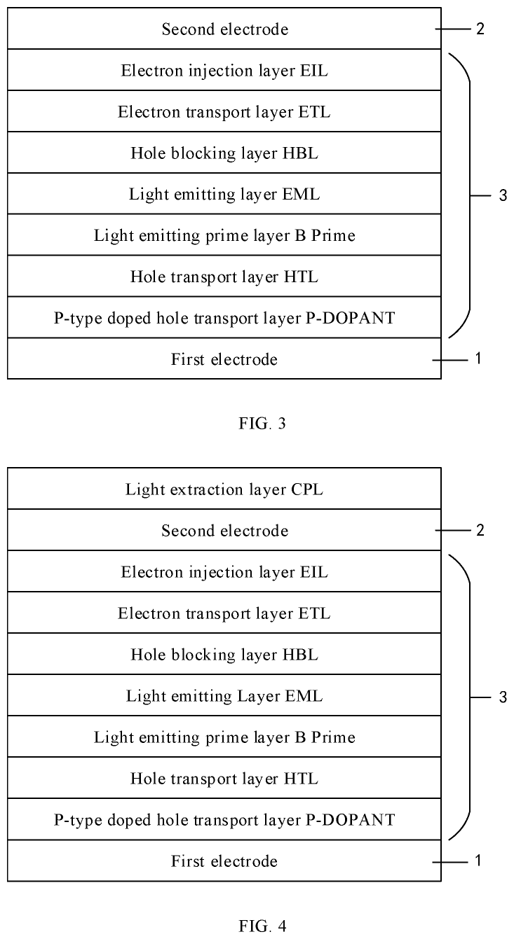

In some embodiments, FIG. 3 is a schematic diagram of a specific structure of a light emitting unit according to an embodiment of the present disclosure. As shown in FIG. 3, the light emitting unit 3 further includes functional sub-layers, including at least one of a P-type doped hole transport layer P-DOPANT, a hole transport layer HTL, a light emitting prime layer B Prime, a hole blocking layer HBL, an electron transport layer ETL and an electron injection layer EIL.

Illustratively, as shown in FIG. 3, the functional sub-layers include the P-type doped hole transport layer P-DOPANT, the hole transport layer HTL, the light emitting prime layer B Prime, the hole blocking layer HBL, the electron transport layer ETL, and the electron injection layer EIL. Specifically, the light emitting unit 3 includes the P-type doped hole transport layer P-DOPANT, the hole transport layer HTL, the light emitting prime layer B Prime, the light emitting layer EML, the hole blocking layer HBL, the electron transport layer ETL, and the electron injection layer EIL sequentially disposed in a direction from the anode to the cathode of the light emitting device.

The light emitting mechanism of the light emitting device is: when a voltage is applied between the anode and the cathode, holes injected from the anode are transported to the light emitting prime layer B Prime through the P-type doped hole transport layer P-DOPANT and the hole transport layer HTL under the driving of the external voltage. There is a difference between energy levels of the anode and of the hole transport layer HTL, so that ohmic contact is formed, which hinders the hole transport. The P-type doped hole transport layer P-DOPANT is made of a material with a deeper energy level, and is located between the anode and of the hole transport layer HTL, so that a hole channel may be formed, the loss of hole transport is reduced as much as possible, and the efficiency of hole transport is improved. The holes are transported by the light emitting prime layer B Prime into the light emitting layer EML. Here, the light emitting prime layer B Prime is able to block electrons from entering the light emitting layer EML. Electrons injected from the cathode are transferred to the hole blocking layer HBL through the electron injection layer EIL and the electron transport layer ETL, and the electrons are transported by the hole blocking layer HBL to the light emitting layer EML, and the hole blocking layer HBL also serves to block the holes from entering the light emitting layer EML. The holes and the electrons entering the light emitting layer EML are recombined in the recombination region to form excitons, thereby emitting light by radiative transition of the excitons, that is, achieving the electroluminescence.

In some embodiments, in order to obtain better device performance, in a case where the functional sub-layers include the light emitting prime layer B Prime, the lowest triplet energy level T1 of a material of the light emitting prime layer B Prime is greater than 2.7 ev. In the case where the functional sub-layers include the hole blocking layer HBL, the lowest triplet energy level T1 of a material of the hole transport layer HTL is greater than 2.7 ev. It should be noted that the energy level T1 of the entire light emitting layer EML is higher, and therefore, with the higher energy level T1 of the transport layer here, the excitons in the light emitting layer EML can be limited in the light emitting layer EML as much as possible, the problem of exciton loss in the light emitting layer EML caused by the fact that the excitons enter the light emitting prime layer B Prime and the hole blocking layer HBL is avoided, thereby ensuring the emitting light by radiative transition of the excitons in the light emitting layer EML, and improving the light emitting efficiency.

In some embodiments, the at least one light emitting unit 3 includes one light emitting unit 3. Thicknesses of layers in the light emitting unit 3 are as follows: under the condition that the functional sub-layers include the P-type doped hole transport layer P-DOPANT, a thickness of the P-type doped hole transport layer P-DOPANT is between 2 nm and 50 nm; under the condition that the functional sub-layers include the hole transport layer HTL, a thickness of the hole transport layer HTL is between 5 nm and 200 nm; under the condition that the functional sub-layers include the light emitting prime layer B Prime, a thickness of the light emitting prime layer B Prime is between 3 nm and 30 nm; a thickness of the light emitting layer EML is between 5 nm and 50 nm; under the condition that the functional sub-layers include the hole blocking layer HBL, a thickness of the hole blocking layer HBL is between 3 nm and 30 nm; under the condition that the functional sub-layers include the electron transport layer ETL, a thickness of the electron transport layer ETL is between 10 nm and 40 nm; and under the condition that the functional sub-layers include the electron injection layer EIL, a thickness of the electron injection layer EIL is between 0.5 nm and 5 nm.

With the thicknesses of the layers in the light emitting unit 3 in the above predetermined range, a condition of a resonant micro-cavity formed between the cathode and the anode can be satisfied. For example, a light emitting center of the light emitting layer EML is located in the vicinity of an antinode of a resonance wave of the resonant micro-cavity, so that the light emitting device has higher efficiency and superior device performance can be obtained.

In some embodiments, the host material includes a P-type material; the P-type material includes a material containing one of the molecular structures of CBP, MCBP, carbazole, triphenylamine; alternatively, the P-type material includes a material containing one of the molecular structures of a CBP derivative, a carbazole derivative, and a triphenylamine derivative. The P-type material selected here is a material with a higher energy level T1.

For example, if the host material is a single material, the host material may be the P-type material; the P-type material may be a hole transport type material, such as a material containing one of the molecular structures of CBP, MCBP, carbazole, triphenylamine; or a material containing one of the molecular structures of a CBP derivative, a carbazole derivative, and a triphenylamine derivative.

Alternatively, the host material may be a mixture of materials, and the mixture of materials may include the P-type material.

In some embodiments, the host material includes an N-type material; the N-type material includes a material containing one of the molecular structures of pyridine, triazine, phenylimidazole; alternatively, the N-type material includes a material containing one of the molecular structures of a pyridine derivative, a triazine derivative, and a phenylimidazole derivative. The N-type material selected here is a material with a high energy level T1.

For example, if the host material is a single material, the host material may be an N-type material; the N-type material may be an electron transport type material, such as a material containing one of the molecular structures of pyridine, triazine, phenylimidazole; or a material containing one of the molecular structures of a pyridine derivative, a triazine derivative, and a phenylimidazole derivative.

Alternatively, the host material may be a mixture of materials, which may be N-type material.

In some embodiments, the host material includes a bipolar material capable of transporting holes and electrons, wherein a ratio of a first mobility of the bipolar material for transporting electrons to a second mobility of the bipolar material for transporting holes is between 1 and 10.

For example, if the host material is a single material, the host material may be the bipolar material. The bipolar material is a material containing both the hole transport type material and the electron transport type material. For example, the bipolar material is a random combination of a material containing one of the molecular structures of pyridine, triazine, and phenylimidazole and a material containing one of the molecular structures of pyridine derivative, triazine derivative, and phenylimidazole derivative.

Alternatively, the host material may be a mixture of materials, and the mixture of materials may include the bipolar material.

In some embodiments, the host material includes a first host material and a second host material, wherein the first host material may be the P-type material and the second host material may be the N-type material. For specific examples of the P-type material and the N-type material, reference may be made to the description of the above embodiments, and repeated descriptions are omitted.

In some embodiments, the host material is a mixture of P-type and N-type materials. In operation, excitons in the light emitting layer EML are recombined to form exciplexes. The peak of the photoluminescence spectrum of the host material is between 360 nm and 520 nm.

In some embodiments, if the host material is the mixture of the P-type material and the N-type material, in order to obtain the better device performance, the highest occupied molecular orbital (HOMO) energy level of the host material may be set to be between −5.2 eV and −6.0 eV; the lowest unoccupied molecular orbital (LUMO) energy level of the host material may be set to be between −2.1 eV and −2.8 eV.

In some embodiments, the host material has a bandgap of less than 3.7 ev; the bandgap of the host material is an absolute value of a difference between the HOMO energy level and the LUMO energy level of the host material.

Illustratively, if the host material is the mixture of the P-type material and the N-type material, in order to obtain the better device performance, the HOMO energy level may be set to be between −5.2 eV and −6.0 eV; the LUMO energy level may be set to be between −2.1 eV and −2.8 eV, and the bandgap Eg of the host material may be set to be less than 3.7 ev; Eg=|HOMO (of the host material)-LUMO (of the host material)|.

In some embodiments, the host material includes a first host material, a second host material, and a third host material, wherein the first host material is the P-type material, the second host material is the N-type material, and the third host material is the bipolar material.

The P-type material and the N-type material have different transmission performances on the holes and the electrons, so that a bipolar material is added between the P-type material and the N-type material in the embodiment. The bipolar material has dual transmission capability of simultaneously transmitting the holes and the electrons, so that the difference between the transmission performances of the P-type material and the N-type material can be compromised, the efficiency of the light emitting device is further improved, and the better device performance is obtained.

In some embodiments, the phosphorescent guest material includes a coordination compound of platinum Pt or a coordination compound of iridium Ir, such as FIrpic, Ir(MDQ)2(acac) or Ir(ppy)2(acac), etc., or derivatives of similar structures containing FIrpic, Ir(MDQ)2(acac) or Ir(ppy)2(acac), etc.

In some embodiments, the fluorescent guest material includes a material containing one of the molecular structures of indolocarbazole, pyrene; alternatively, the fluorescent guest material includes a material containing one of molecular structures of an indolocarbazole derivative and a pyrene derivative.

In some embodiments, a material of the light emitting prime layer B Prime and a material of the hole blocking layer HBL may be the same as one material in the host material.

In order to obtain the better device performance, the light emitting device will be specifically described below as a complete example in the present disclosure. In one embodiment, the light emitting layer EML includes the host material, the phosphorescent guest material, and the fluorescent guest material doped together. The T1 energy level of the phosphorescent guest material is between 2.7 eV and 3.0 eV, the peak of the photoluminescence spectrum of the phosphorescent guest material is between 420 nm and 500 nm, and the peak width at half height of the photoluminescence spectrum of the phosphorescent guest material is less than 120 nm. The peak of the absorption spectrum of the fluorescent guest material is between 420 nm and 480 nm, and the peak of the photoluminescence spectrum of the fluorescent guest material is between 440 nm and 500 nm. The host material is a mixture of the P-type material and the N-type material, wherein the T1 energy level of at least one material is greater than the T1 energy level of the phosphorescent guest material; the peak of the photoluminescence spectrum of at least one material is between 360 nm and 420 nm. The HOMO energy level of the host material is between −5.2 eV and −6.0 eV; the LUMO energy level of the host material is between −2.1 eV and −2.8 eV, and the band gap Eg of the host material is less than 3.7 eV. In the case where the functional sub-layers include the light emitting prime layer B Prime, the T1 energy level of the material of the light emitting prime layer B Prime is >2.7 ev; in the case where the functional sub-layers include the hole blocking layer HBL, the T1 energy level of the material of the hole transport layer HTL is >2.7 ev. With such the preferred combination, the higher efficiency and the longer service life of the light emitting device can be obtained.

In some embodiments, FIG. 4 is a schematic diagram of another specific structure of a light emitting device according to an embodiment of the present disclosure. As shown in FIG. 4, the light emitting device further includes a light extraction layer CPL disposed on a side of the second electrode 2 away from the first electrode 1, and configured to effectively extract the light emitted on a side of the second electrode 2 while protecting the second electrode 2.

Here, FIG. 4 shows a top emission device, i.e. the second electrode 2 is a cathode. Alternatively, the light emitting device of the embodiment of the present disclosure may be a bottom emission device, in which case the second electrode 2 is an anode.

In some embodiments, the light extraction layer CPL has a thickness between 30 nm to 100 nm.

In addition, the host material in the present disclosure includes a mixture of a plurality of materials, such as the P-type material and the N-type material. It should be noted that in the process of forming the light emitting layer EML, a “four-source co-evaporation” method may be adopted. Specifically, the P-type material P host, the N-type material N host, the phosphorescent guest material PBD, and the fluorescent guest material FBD are respectively placed in separate evaporation sources, and are simultaneously evaporated by using four different evaporation sources, to form the light emitting layer EML. Since each material has its own evaporation source, the method does not require consideration of the influence among the materials, and therefore the method may be used to select materials from a wider range. Alternatively, in the process of forming the light emitting layer EML, a “three-source co-evaporation” method may also be adopted. Specifically, the P-type material P host and the N-type material N host are pre-mixed and then placed in the same evaporation source, and the phosphorescent guest material PBD and the fluorescent guest material FBD are respectively placed in separate evaporation sources, and a mixed material of the P-type material P host and the N-type material N host, the phosphorescent guest material PBD and the fluorescent guest material FBD are simultaneously evaporated by the three different evaporation sources, to form the light emitting layer EML. In the method, due to the fact that the pre-mixing of the P-type material P host and the N-type material N host requires their evaporation temperatures to be close to each other, although the number of the evaporation sources can be reduced by means of the pre-mixing and evaporating, the method may be used to select materials from a smaller range compared with the four-source evaporation method. For the above two methods for forming the light emitting layer EML, a preferable method may be selected according to practical application, which is not particularly limited in the embodiment of the present disclosure.

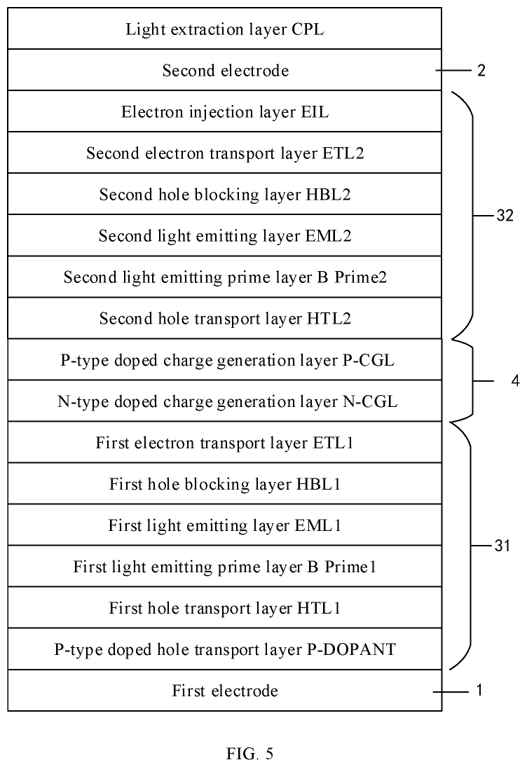

In some embodiments, FIG. 5 is a schematic diagram of a specific structure of a tandem light emitting device according to an embodiment of the present disclosure. As shown in FIG. 5, at least one light emitting unit 3 includes a plurality of light emitting units; the light emitting device further includes a charge separation generation unit 4 disposed between every two adjacent light emitting units 3.

FIG. 5 only shows a case where the light emitting device includes two light emitting units 3 connected in series. A layer structure including more other light emitting units 3 is similar to the layer structure including the two light emitting units 3. For example, the charge separation generation units 4 and the other light emitting units 3 are added on the basis of one light emitting unit 3, the case of more than two light emitting units 3 is not repeated in the present disclosure.

Each charge separation generation unit 4 includes an N-type doped charge generation layer N-CGL and a P-type doped charge generation layer P-CGL; the N-type doped charge generation layer N-CGL may be understood as an N-type organic semiconductor, and the P-type doped charge generation layer P-CGL may be understood as a P-type organic semiconductor. The N-type doped charge generation layer N-CGL and the P-type doped charge generation layer P-CGL may form a P/N junction structure; the electrons and the holes may be generated at an interface between the N-type doped charge generation layer N-CGL and the P-type doped charge generation layer P-CGL, and the electrons and the holes are separated; the N-type doped charge generation layer N-CGL transmits the electrons to a first light emitting unit 31, and the P-type doped charge generation layer P-CGL transmits the holes to a second light emitting unit 32. The first light emitting unit 31 and the second light emitting unit 32 are adjacent light emitting units 3.

As further shown in FIG. 5, the first light emitting unit 31 includes a P-type doped hole transport layer P-DOPANT, a first hole transport layer HTL1, a first light emitting prime layer B Prime1, a first light emitting layer EML1, a first hole blocking layer HBL1, and a first electron transport layer ETL1, which are sequentially disposed in a direction from the first electrode 1 to the second electrode 2. The second light emitting unit 32 includes a second hole transport layer HTL2, a second light emitting prime layer B Prime2, a second light emitting layer EML2, a second hole blocking layer HBL2, a second electron transport layer ETL2, and an electron injection layer EIL, which are sequentially disposed in a direction from the first electrode 1 to the second electrode 2. Here, as an example, the first light emitting layer EML1 and the second light emitting layer EML2 are both blue light emitting layers B-EML for description.

In some embodiments, for the tandem light emitting device, in order to obtain a better device performance, the thicknesses of layers in the light emitting device are adjusted reasonably. Specifically, under the condition that the functional sub-layers include the hole transport layer HTL, a thickness of the hole transport layer HTL is between 10 nm and 300 nm; under the condition that the functional sub-layers include the light emitting prime layer B Prime, a thickness of the light emitting prime layer B Prime is between 3 nm and 80 nm; a thickness of the light emitting layer EML is between 10 nm and 40 nm; under the condition that the functional sub-layers include the hole blocking layer HBL, a thickness of the hole blocking layer HBL is between 5 nm and 20 nm; under the condition that the functional sub-layers include the electron transport layer ETL, a thickness of the electron transport layer ETL is between 10 nm and 30 nm; a thickness of the N-type doped charge generation layer N-CGL and a thickness of the P-type doped charge generation layer P-CGL are both between 5 nm and 30 nm.

In the embodiment, a definition of a thickness of the hole transport layer HTL includes a definition of a thickness of the first hole transport layer HTL1 and a thickness of the second hole transport layer HTL2; a definition of a thickness of the light emitting prime layer B Prime includes a definition of a thickness of the first light emitting prime layer B Prime1 and a thickness of the second light emitting prime layer B Prime2; a definition of a thickness of the hole blocking layer HBL includes a definition of a thickness of the first hole blocking layer HBL1 and a thickness of the second hole blocking layer HBL2; a definition of a thickness of the electron transport layer ETL includes a definition of a thickness of the first electron transport layer ETL1 and a thickness of the second electron transport layer ETL2.

With the thicknesses of the layers in the light emitting units 3 connected in series in the above predetermined range, a condition of a resonant micro-cavity formed between the cathode and the anode can be satisfied. For example, a light emitting center of the light emitting layer EML is located in the vicinity of an antinode of a resonance wave of the resonant micro-cavity, so that the tandem light emitting device has higher efficiency and superior device performance can be obtained.

In some embodiments, materials of the N-type doped charge generation layer N-CGL and of the P-type doped charge generation layer P-CGL may be selected from any one of the following materials: 1) N-type doped organic layers/inorganic metal oxides, such as Alq3:Mg/WO3, Bphen:Li/MoO3. Alq3:Mg represents Mg doped in Alq3. Bphen:Li represents Li doped in Bphen. 2) N-type doped organic layers/a single organic layer, such as Alq3:Li/HATCN. Alq3:Li represents Li doped in Alq3. 3) N-type doped organic layers/p-type doped organic layers, such as Alq3:Li/NPB:FeCl3, Alq3:Mg/m-MTDATA:F4-TCNQ. NPB:FeCl3 represents FeCl3 doped in NPB. m-MTDATA:F4-TCNQ represents F4-TCNQ doped in m-MTDATA. 4) Un-doped, that is, the material of the N-type doped charge generation layer N-CGL and the material of the P-type doped charge generation layer P-CGL are both un-doped, such as: 16CuPc/CuPc, Al/WO3/Au.

It should be noted that here, the material before “/” is the material of the N-type doped charge generation layer N-CGL, and the material after “/” is the material of the P-type doped charge generation layer P-CGL. For Al/WO3/Au, wherein Al is the material of the N-type doped charge generation layer N-CGL, WO3 is the material of the P-type doped charge generation layer P-CGL, and Au is the material for assisting the injection of the holes and the electrons in the N-type doped charge generation layer N-CGL and the P-type doped charge generation layer P-CGL.

The above description has been given by taking the light emitting device as the blue light emitting device as an example. Alternatively, in the embodiment of the present disclosure, the light emitting device may be a light emitting device that emits light of another color than blue light, such as a white light emitting device or a quantum dot light emitting device.

In some embodiments, the light emitting device is a white light emitting device as an example. The white light emitting device includes a plurality of light emitting units, wherein the light emitting layer of at least one of the light emitting units emits light with a wavelength between 440 nm and 480 nm. The white light emitting device includes two light emitting units as an example, the light emitting layer of one light emitting unit emits light with a wavelength between 440 nm and 480 nm, and the other light emitting unit includes two light emitting layers stacked together, wherein one light emitting layer emits light with a wavelength between 600 nm and 640 nm, and the other light emitting layer emits light with a wavelength between 510 nm and 550 nm.

Illustratively, the light emitting device includes two light emitting units 3, wherein the light emitting layer of one light emitting unit 3 is the blue light emitting layer B-EML, and the light emitting layer of the other light emitting unit 3 is a red light emitting layer R-EML and a green light emitting layer G-EML stacked together. At this time, the light emitting device may emit white light.

Illustratively, the light emitting device includes two light emitting units 3, wherein the light emitting layer of one light emitting unit 3 is the blue light emitting layer B-EML, and the light emitting layer of the other light emitting unit 3 is the red light emitting layer R-EML or the green light emitting layer G-EML, or a light emitting layer of other color.

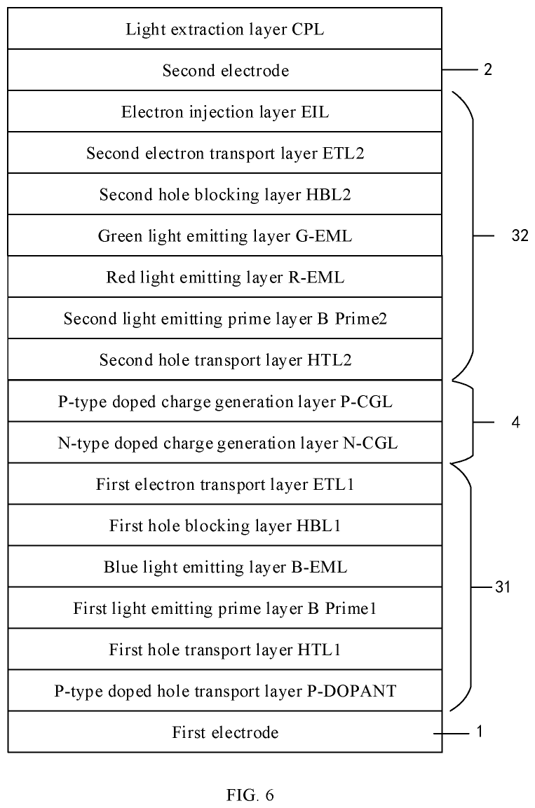

FIG. 6 is a schematic diagram of a specific structure of another tandem light emitting device according to an embodiment of the present disclosure. As shown in FIG. 6, the tandem light emitting device is the white light emitting device. The at least one light emitting unit 3 includes a plurality of light emitting units. In FIG. 6, only two light emitting units 3 are included, as an example. The light emitting device further includes the charge separation generation unit 4 disposed between the two adjacent light emitting units 3. The light emitting layer of one of the light emitting units 31 is the blue light emitting layer B-EML, and the light emitting layer of the other light emitting unit 32 includes the red light emitting layer R-EML and the green light emitting layer G-EML stacked together. Here, the red light emitting layer R-EML may be disposed at a position closer to the first electrode 1 than the green light emitting layer G-EML, or the red light emitting layer R-EML may be disposed at a position farther from the first electrode 1 than the green light emitting layer G-EML.

For the blue light emitting layer B-EML in this embodiment, reference may be made to the specific description of the light emitting layer EML in the blue light emitting device, and repeated descriptions are omitted. The functional sub-layers in the light emitting unit 3 are the same as those in the blue light emitting device, and the repeated description is omitted.

The blue light emitting layer B-EML in the tandem light emitting device is properly designed in the embodiment, thereby improving the efficiency and the service life of the blue light emitting layer, and further improving the efficiency and the service life of the whole light emitting device.

The light emitting device provided by the embodiment of the present disclosure meets the above conditions, so that the energy transfer between the phosphorescent guest material and the fluorescent guest material can have a higher conversion rate, and the color purity of the blue light emitting device can be improved, thereby obtaining the blue light emitting device with a better performance. It can be seen from the experimental result that the service life of the device is prolonged to more than 300% of that of a pure phosphorescent device under the condition that the efficiency of the device is reduced by less than 5%, so that the requirement of mass production can be met, and the efficiency is improved by more than 50% compared with the blue fluorescent device in mass production at present.

The light emitting device according to the embodiment of the present disclosure has been fully described as above.

In addition, the embodiment of the present disclosure further provides a display panel, including the light emitting device according to any one of the above embodiments. The display panel may be any product with a display function, such as a mobile phone, a tablet computer, a television, a display, a notebook computer, a digital photo frame, a vehicle-mounted device, or the like. Other essential components of the display panel should be understood by one of ordinary skill in the art, and are not described herein and should not be construed as limiting the present disclosure.

It should be understood that, the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A light emitting device, comprising a first electrode, a second electrode, and at least one light emitting unit between the first electrode and the second electrode; wherein the at least one light emitting unit each comprises at least a light emitting layer; wherein the light emitting layer comprises a host material, a phosphorescent guest material and a fluorescent guest material which are doped together; and
a lowest triplet energy level of at least one material in the host material is greater than a lowest triplet energy level of the phosphorescent guest material.

2. The light emitting device according to claim 1, wherein the light emitting layer of at least one of the at least one light emitting unit emits light with a wavelength between 440 nm and 480 nm.

3. The light emitting device according to claim 2, wherein a peak of a photoluminescence spectrum of the phosphorescent guest material is between 440 nm and 520 nm; and
a peak width at half height of the photoluminescence spectrum of the phosphorescent quest material is less than 160 nm.

4. (canceled)

5. The light emitting device according to claim 3, wherein a peak of an absorption spectrum of the fluorescent guest material is between 420 nm and 480 nm.

6. The light emitting device according to claim 2, wherein a peak of a photoluminescence spectrum of the fluorescent guest material is between 440 nm and 520 nm.

7. The light emitting device according to claim 2, wherein the lowest triplet energy level of the phosphorescent guest material is between 2.6 ev and 3.2 ev.

8. The light emitting device according to claim 2, wherein a peak of a photoluminescence spectrum of the at least one material included in the host material is between 360 nm and 500 nm.

9. The light emitting device according to claim 2, wherein a peak width at half height of an electroluminescence spectrum of the light emitting device is less than 80 nm.

10. The light emitting device according to claim 1, wherein the host material is a mixture of at least two materials.

11. The light emitting device according to claim 1, wherein the host material is a mixture of at least two materials; and the at least two materials in the light emitting layer interact on each other to form exciplexes in operation; and
a peak of a photoluminescence spectrum of the host material is between 360 μm and 520 nm.

12. (canceled)

13. The light emitting device according to claim 1, wherein the host material is a mixture of at least two materials; and a minimum mixing proportion of any one of the at least two materials is greater than 5%;
wherein a doping concentration of the phosphorescent quest material is between 1% and 30%; and
wherein a doping concentration of the fluorescent quest material is between 0.1% and 5%.

14-15. (canceled)

16. The light emitting device according to claim 1, wherein the light emitting unit further comprises functional sub-layers; and the functional sub-layers comprise at least one of a P-type doped hole transport layer, a hole transport layer, a light emitting prime layer, a hole blocking layer, an electron transport layer and an electron injection layer; and
wherein the functional sub-layers comprise the light emitting layer, and a lowest triplet energy level of a material of the light emitting prime layer is greater than 2.7 ev; and
the functional sub-layers comprise the hole blocking layer, and a lowest triplet energy level of a material of the hole transport layer is greater than 2.7 ev.

17. (canceled)

18. The light emitting device according to claim 1, wherein the light emitting unit further comprises functional sub-layers; and the functional sub-layers comprise at least one of a P-type doped hole transport layer, a hole transport layer, a light emitting prime layer, a hole blocking layer, an electron transport and an electron injection laver;
wherein the at least one light emitting unit comprises one light emitting unit;
the functional sub-layers comprise the P-type doped hole transport layer, and a thickness of the P-type doped hole transport layer is between 2 nm and 50 nm;
the functional sub-layers comprise the hole transport layer, and a thickness of the hole transport layer is between 5 nm and 200 nm;
the functional sub-layers comprise the light emitting prime layer, and a thickness of the light emitting prime layer is between 3 nm and 30 nm;
a thickness of the light emitting layer is between 5 nm and 50 nm;
the functional sub-layers comprise the hole blocking layer, and a thickness of the hole blocking layer is between 3 nm and 30 nm;
the functional sub-layers comprise the electron transport layer, and a thickness of the electron transport layer is between 10 nm and 40 nm; and
the functional sub-layers comprise the electron injection layer, and a thickness of the electron injection layer is between 0.5 nm and 5 nm.

19. The light emitting device according to claim 1, wherein the light emitting unit further comprises functional sub-layers; and the functional sub-layers comprise at least one of a P-type doped hole transport layer, a hole transport layer, a light emitting prime layer, a hole blocking layer, an electron transport layer and an electron injection layer;
wherein the at least one light emitting unit comprises a plurality of light emitting units; and the light emitting device further comprises a charge separation generation unit between two adjacent light emitting units;
wherein the functional sub-layers comprise the hole transport layer, and a thickness of the light emitting prime layer is between 10 nm and 300 nm;
the functional sub-layers comprise the light emitting prime layer, a thickness of the light emitting prime layer is between 3 nm and 80 nm;
a thickness of the light emitting prime layer is between 10 nm and 40 nm;
the functional sub-layers comprise the hole blocking layer, a thickness of the hole blocking layer is between 5 nm and 20 mm;
the functional sub-layers comprise the electron transport layer thickness of the electron transport layer is between 10 nm and 30 nm; and
the charge separation generation unit comprises an N-type doped charge generation layer and a P-type doped generation layer; and a thickness of the N-type doped charge generation layer and a thickness of the P-type doped charge generation layer are both between 5 nm and 30 mm.

20. (canceled)

21. The light emitting device according to claim 1, wherein the host material comprises a P-type material; the P-type material comprises a material containing one of molecular structures of CBP, MCBP, carbazole and triphenylamine; or the P-type material comprises a material containing one of molecular structures of a CBP derivative, a carbazole derivative and a triphenylamine derivative.

22. The light emitting device according to claim 1, wherein the host material comprises an N-type material; the N-type material comprises a material containing one of molecular structures of pyridine, triazine and phenylimidazole; or the N-type material comprises a material containing one of molecular structures of a pyridine derivative, a triazine derivative and a phenylimidazole derivative.

23. The light emitting device according to claim 1, wherein the host material comprises a bipolar material, and a ratio of a first mobility of the bipolar material for transporting electrons to a second mobility of the bipolar material for transporting holes is between 1 and 10.

24. The light emitting device according to claim 1, wherein the host material comprises a first host material and a second host material, the first host material is a P-type material and the second host material is an N-type material;
wherein a highest occupied molecular orbital (HOMO) energy level of the host material is between −5.2 ev and −6.0 ev; and a lowest unoccupied molecular orbital (LUMO) energy level of the host material is between −2.1 eV and −2.8 eV; and
wherein a bandgap of the host material is less than 3.7 ev, and the bandgap of the host material is an absolute value of a difference between the HOMO energy level and the LUMO energy level of the host material.

25-26. (canceled)

27. The light emitting device according to claim 1, wherein the host material comprises a first host material, a second host material and a third host material, wherein the first host material is a P-type material, the second host material is an N-type material, and the third host material is a bipolar material;
wherein the phosphorescent guest material comprises a coordination compound of a platinum or a coordination compound of iridium; and
wherein the fluorescent guest material comprises a material containing one of molecular structures indolocarbazole and pyrene; or the fluorescent guest material comprises a material containing one of molecular structures of an indolocarbazole derivative and a pyrene derivative.

28-29. (canceled)

30. A display panel, comprising the light emitting device according to claim 1.
